(19) United States
(12) Patent Application Publication
(10) Pub. No.: US 2018/0344027 A1
(43) Pub. Date: Dec. 6, 2018

(54) Magnetically Attached Removable Tabletop

(71) Applicants: David R. Hall, Provo, UT (US); William H. Reynolds, Orem, UT (US); Christopher Reynolds, Orem, UT (US); Joseph Blanch, Provo, UT (US); Joe Fox, Spanish Fork, UT (US); Nathan Davis, Bountiful, UT (US)

(72) Inventors: David R. Hall, Provo, UT (US); William H. Reynolds, Orem, UT (US); Christopher Reynolds, Orem, UT (US); Joseph Blanch, Provo, UT (US); Joe Fox, Spanish Fork, UT (US); Nathan Davis, Bountiful, UT (US)

(21) Appl. No.: 15/615,524

(22) Filed: Jun. 6, 2017

(51) Int. Cl. A47B 47/02; H01L 43/00; A47B 87/00; F16B 12/08; A47B 13/14

(52) U.S. Cl. CPC A47B 47/02; H01L 43/00; A47B 25/00; F16B 12/08; A47B 13/14; A47B 87/00

(57) ABSTRACT

A table comprising a table base and a tabletop is disclosed. The table base comprises a top surface comprising a rotatable portion comprising one or more permanent magnets. The rotatable portion rotates independently from the table base. At least a portion of the tabletop comprises a ferromagnetic material. The tabletop further comprises a usable first side and a usable second side alternately mounted to the table base by an attractive force between the ferromagnetic material and the one or more permanent magnets. Rotation of the rotatable portion of the top surface, such that the one or more permanent magnets are oriented away from the ferromagnetic material, engages or disengages the attractive force.

### FIELD OF THE INVENTION

This invention relates generally to tables with interchangeable tabletops. More particularly, we are interested in tabletops wherein both sides can be attached via magnets.

### BACKGROUND

The table has been in use for the duration of recorded history in various forms. Tables are attached in many ways, such as bolts, clamps, and compression. However, tables are almost universally a one-sided device. One side is used for the tabletop, with the other side acting as the attachment point. This limits the table to having one surface. The ability to interchangeably utilize both sides of a tabletop without the need for attachment methods that leave holes, damage surfaces, or require extensive effort is needed.

U.S. Pat. No. 2,675,288, to Usher teaches an interchangeable utility table. The table is convertible into a drawing desk. The present disclosure differs from this prior art disclosure in that the prior art disclosure uses hinges to modify the table surface, does not use magnetic materials to attach the tabletop to the base, and doesn't allow for both sides of the tabletop to be attached to the base. This prior art disclosure is pertinent and may benefit from the devices disclosed herein and is hereby incorporated for reference in its entirety for all that it teaches.

United States patent publication number 20070039101, to Luginbuhl, et al., teaches specialized tabletops for medical imaging. Interchangeable specialized tabletops are provided, each constructed for specific uses, such as tomographic imaging. The present disclosure differs from this prior art disclosure in that the prior art disclosure does not use magnetic materials to attach the tabletop to the base and the two sides of each tabletop are not both able to be attached to the table base. This prior art disclosure is pertinent and may benefit from the devices disclosed herein and is hereby incorporated for reference in its entirety for all that it teaches.

U.S. Pat. No. 5,131,105, to Harrawood, et al., teaches a patient support table. The table consists of interchangeable table supports and tabletops that are x-ray translucent. The present disclosure differs from this prior art disclosure in that the prior art disclosure does not use magnetic materials to attach the tabletop to the base and the two sides of each tabletop are not both able to be attached to the table base. This prior art disclosure is pertinent and may benefit from the devices disclosed herein and is hereby incorporated for reference in its entirety for all that it teaches.

U.S. Pat. No. 1,361,420, to Van Dolsen teaches an operating table with interchangeable tabletops. The tabletops are held on with pins and only have one usable surface. The present disclosure differs from this prior art disclosure in that the prior art disclosure does not use magnetic materials to attach the tabletop to the base and the two sides of each tabletop are not both able to be attached to the table base. This prior art disclosure is pertinent and may benefit from the devices disclosed herein and is hereby incorporated for reference in its entirety for all that it teaches.

U.S. Pat. No. 3,241,885, to Deaton, teaches modular furniture and components thereof. This is sectional furniture with multiple components that are usable together, including tabletops and table bases that can be mixed and matched. The present disclosure differs from this prior art disclosure in that the prior art disclosure attaches the tabletops by permanent adhesives, does not use magnetic materials to attach the tabletop to the base, and the two sides of each tabletop are not both able to be attached to the table base. This prior art disclosure is pertinent and may benefit from the devices disclosed herein and is hereby incorporated for reference in its entirety for all that it teaches.

U.S. Pat. No. 5,865,129, to Samples, teaches a knock-down table consisting of a top frame and attachable legs. The top frame has a lip that can hold a tabletop. The present disclosure differs from this prior art disclosure in that the prior art disclosure does not use magnetic materials to attach the tabletop to the base and the two sides of each tabletop are not both able to be attached to the table base. This prior art disclosure is pertinent and may benefit from the devices disclosed herein and is hereby incorporated for reference in its entirety for all that it teaches.

U.S. Pat. No. 1,649,388, to Frank, teaches a changeable-top table. The present disclosure differs from this prior art disclosure in that the prior art disclosure does not use magnetic materials to attach the tabletop to the base and the two sides of each tabletop are not both able to be attached to the table base. This prior art disclosure is pertinent and may benefit from the devices disclosed herein and is hereby incorporated for reference in its entirety for all that it teaches.

U.S. Pat. No. 8,480,091, to Florence, teaches a gaming table with interchangeable layouts. The present disclosure differs from this prior art disclosure in that the prior art disclosure does not use magnetic materials to attach the tabletop to the base and the two sides of each tabletop are not both able to be attached to the table base. This prior art disclosure is pertinent and may benefit from the devices disclosed herein and is hereby incorporated for reference in its entirety for all that it teaches.

U.S. Pat. No. 6,823,804, to Arnell, teaches an interchangeable tabletop. The present disclosure differs from this prior art disclosure in that the prior art disclosure does not use magnetic materials to attach the tabletop to the base, but uses magnetic strips to attach an object to the tabletop. Further, the two sides of each tabletop are not both able to be attached to the table base. This prior art disclosure is pertinent and may benefit from the devices disclosed herein and is hereby incorporated for reference in its entirety for all that it teaches.

U.S. Pat. No. 2,922,505, to De Buigne, teaches an indexing table with an interchangeable rotatable table top with gear mechanisms that cause the table to rotate. The present disclosure differs from this prior art disclosure in that the prior art disclosure does not use magnetic materials to attach the tabletop to the base and the two sides of each tabletop are not both able to be attached to the table base. This prior art disclosure is pertinent and may benefit from the devices disclosed herein and is hereby incorporated for reference in its entirety for all that it teaches.

### SUMMARY

A table comprising a table base and a tabletop is disclosed. The table base comprises a top surface comprising a rotatable portion comprising one or more permanent magnets. The rotatable portion rotates independently from the table base. At least a portion of the tabletop comprises a ferromagnetic material. The tabletop further comprises a usable first side and a usable second side alternately mounted to the table base by an attractive force between the ferromagnetic material and the one or more permanent magnets. Rotation of the rotatable portion of the top surface, such that the one or more permanent magnets are oriented away from the ferromagnetic material, engages or disengages the attractive force.

The one or more permanent magnets may comprise neodymium iron boron magnets, samarium cobalt magnets, aluminum nickel cobalt magnets, ferritic magnets, or combinations thereof.

The first side and the second side may be ferromagnetic. The ferromagnetic material may be contained within an interior portion of the tabletop.

The rotatable portion may comprise cross-bracing tubes horizontal to the tabletop. The cross-bracing tubes may comprise handles to facilitate rotation.

The rotatable portion may comprise one or more legs substantially perpendicular to the tabletop. The one or more permanent magnets may be arrayed in a pattern and the ferromagnetic material may be arrayed in the same pattern such that rotation of the one or more legs causes the pattern to alternately substantially overlap and substantially not overlap. The permanent magnets may comprise an isotropic or anisotropic material comprising at least two magnetic pole orientations.

The rotatable portion may comprise both cross-bracing tubes horizontal to the tabletop and one or more legs substantially perpendicular to the tabletop.

The tabletop may comprise an elevated pattern or patterns, a recessed pattern or patterns, or a combination thereof on the first side, the second side, or the first and the second side.

The first side may comprise a flush-mount touch screen computing device.

The first side may comprise a first smooth, uninterrupted surface and the second side may comprise a second smooth, uninterrupted surface.

The first side and the second side may comprise different materials. The first side and the second side may further comprise bamboo, hard wood, plywood, laminated plywood, laminates, rubber, vinyl, plastics, stainless steel, galvanized steel, carbon steel, black iron, pewter, copper, zinc, aluminum, glass, quartz, granite, marble, stone, ceramics, fiberboards, varnish, sealant, paint, or combinations thereof.

The table base may further comprise metal, wood, plastic, stone, glass, or combinations thereof.

The table may further comprise an electrical inlet or inlets, an electrical outlet or outlets, and an edge computer connection or connections in an edge or edges of the tabletop. The table may further comprise wiring passing through an interior portion of the tabletop between the edge computer connection or connections and a side computer connection or connections on the first side or the second side of the tabletop.

The first side may comprise a heating element or heating elements and the second side may comprise a cooling element or elements.

The first side and the second side may comprise different uses, the uses selected from the group consisting of computer usage, office work, drafting, art, cutting, metal working, working with tools, cooking, dining, gaming, conferencing, displaying, medical, massage, or combinations thereof.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the invention will be described and explained with additional specificity and detail through use of the accompanying drawings, in which:

FIGS. 1A-B show an isometric view of a table and a side view of the table.

FIGS. 2A-C show isometric views of a table and a side view of the table.

FIG. 3 shows an exploded isometric view of a table.

FIGS. 4A-E show an isometric view of a table, a top view and side view of one corner of the table, and a top view and side view of a table leg of the table.

FIGS. 5A-D show isometric views of a table, a detached view of the table, and a cross-sectional detached side view of the table.

FIGS. 6A-B show an isometric view of a table and a side view of the table.

### DETAILED DESCRIPTION

It will be readily understood that the components of the present invention, as generally described and illustrated in the Figures herein, could be arranged and designed in a wide variety of different configurations. Thus, the following more detailed description of the embodiments of the invention, as represented in the Figures, is not intended to limit the scope of the invention, as claimed, but is merely representative of certain examples of presently contemplated embodiments in accordance with the invention.

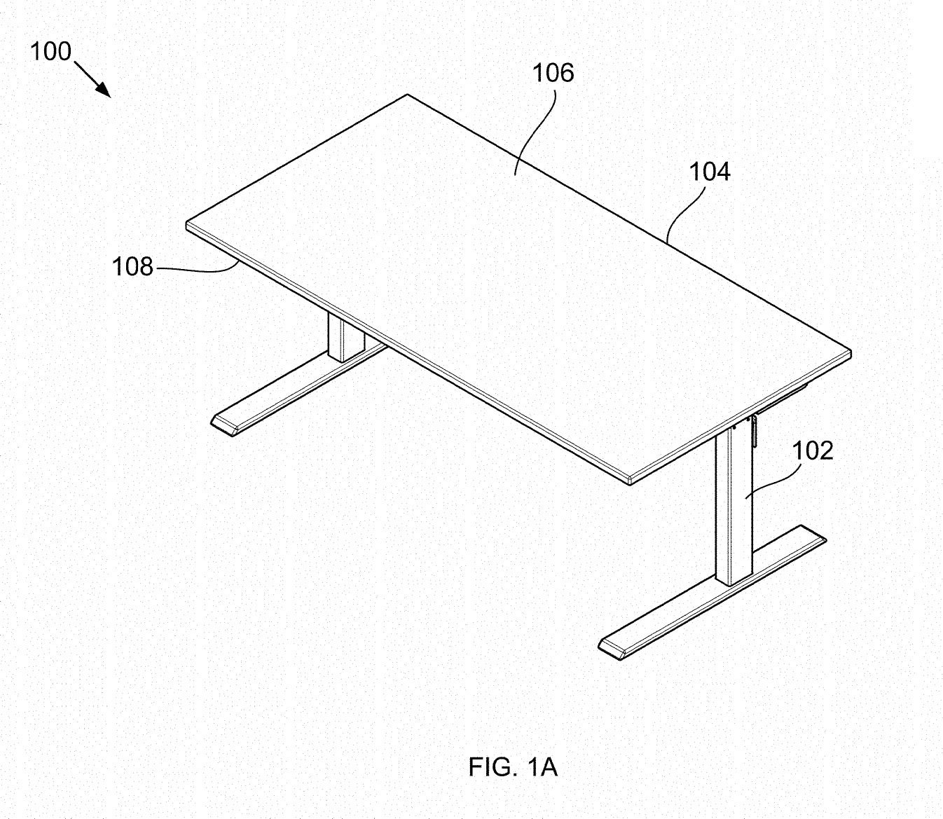

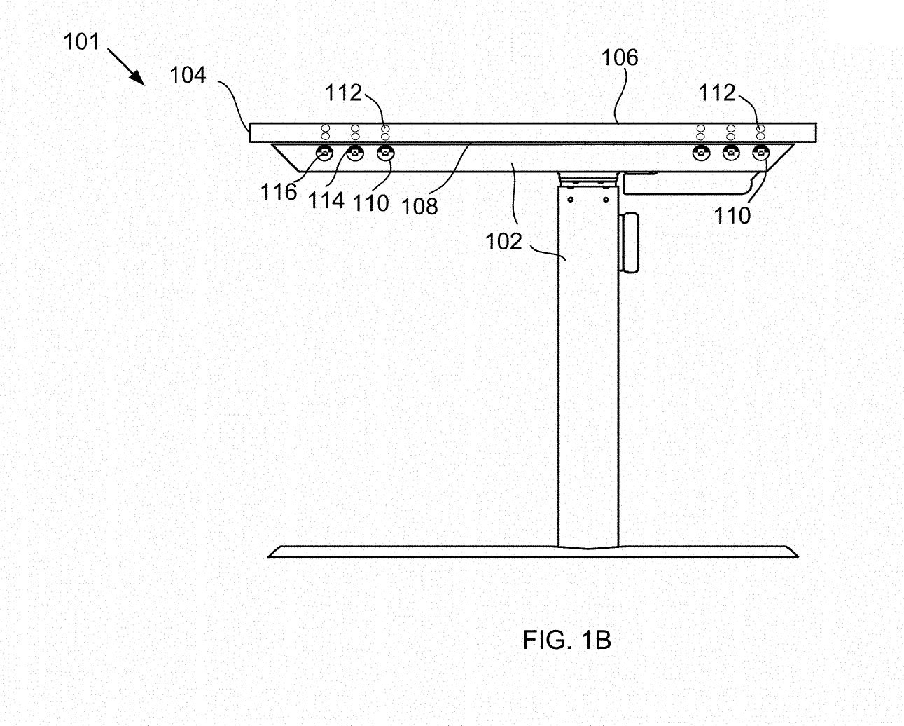

Referring to FIGS. 1A-D, an isometric view of a table is shown at 100 and a side view of the table is shown at 101, as per one embodiment of the present invention. A top surface of table base 102 is provided with rotatable rods 110, containing half-cylinder shaped permanent magnets 114. Tabletop 104 comprises first surface 106 and second surface 108, each surface comprising ferromagnetic material 112 near the surface. These surfaces are alternately mounted to table base 102 by means of attraction between permanent magnets 110 and ferromagnetic materials 112. Rotation of rods 110, using slot 116, engages disengages the magnetic attraction, resulting in tabletop 104 becoming attached or detached. In some embodiments, the surfaces are both smooth and uninterrupted. In some embodiments, first surface 106 is metal and second surface 108 is bamboo. In other embodiments, first surface 106 is copper and second surface 108 is stainless steel. The permanent magnets may comprise an isotropic or anisotropic material comprising at least two magnetic pole orientations.

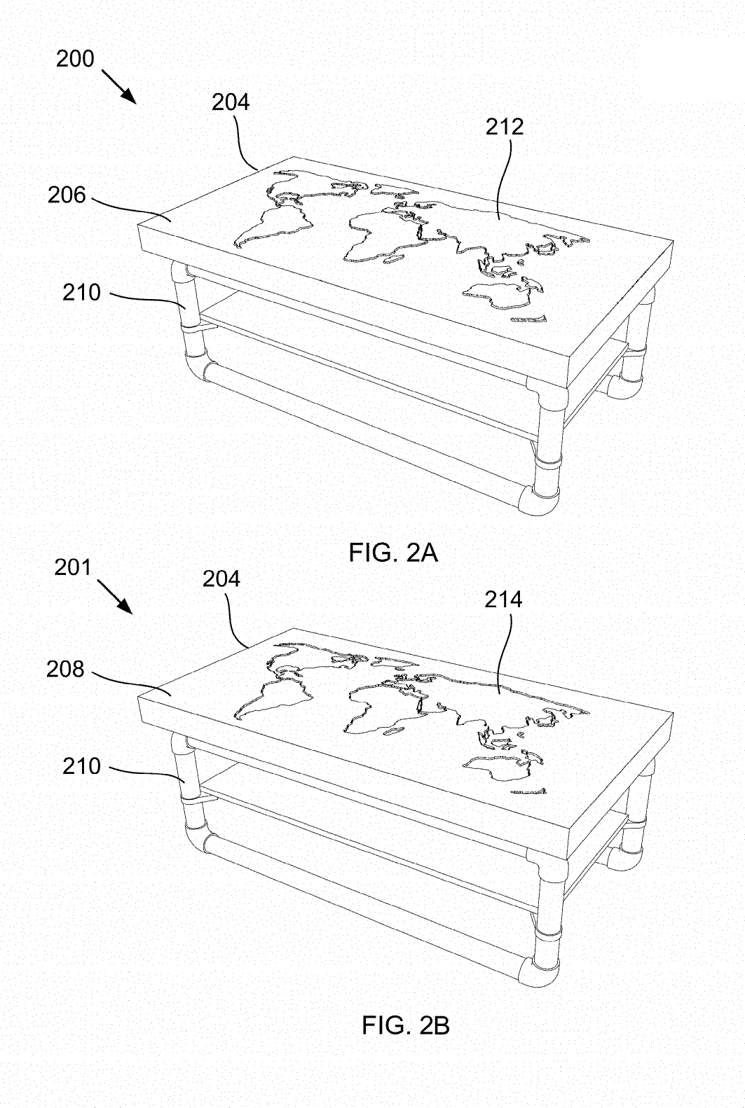

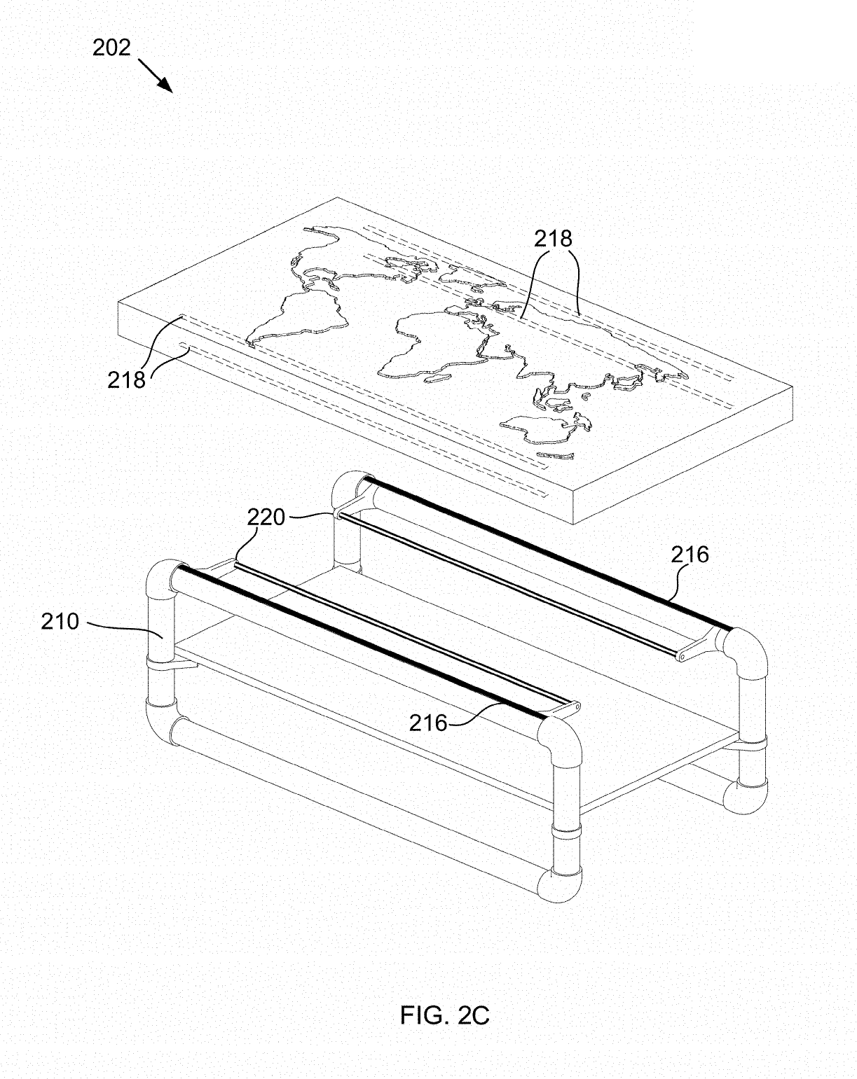

Referring to FIGS. 2A-C, isometric views of a table are shown at 200 and 201 and a side view of the table is shown at 202, as per one embodiment of the present invention. Top surfaces of table base 210 are provided with permanent magnets 216. Tabletop 204 comprises first surface 206 and second surface 208, with ferromagnetic material 218 embedded near the surfaces. The permanent magnets may comprise an isotropic or anisotropic material comprising at least two magnetic pole orientations. These surfaces comprise raised relief map 212 and recessed map 214, respectively, and are alternately mounted to table base 210 by means of attraction between permanent magnets 216 and ferromagnetic materials 218. Handles 220 can be grasped from the side and below and pulled downward, rotating permanent magnets 216 away from ferromagnetic materials 218 sufficient to allow tabletop 204 to be detached from table base 210.

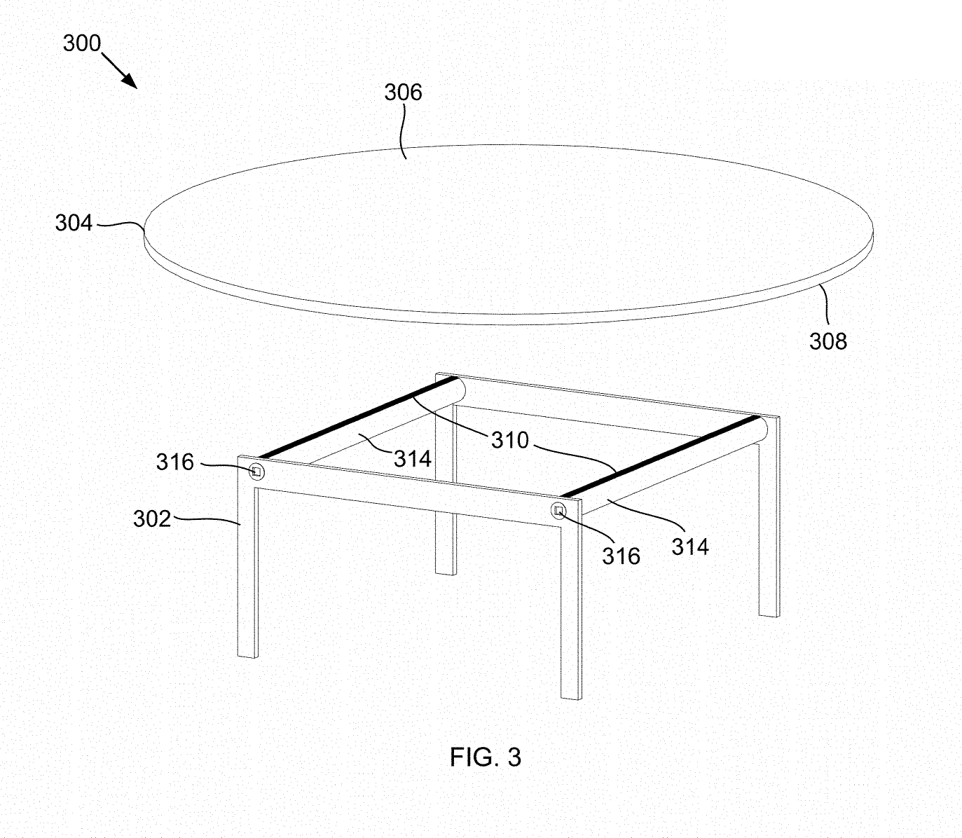

Referring to FIG. 3, an exploded isometric view of a table is shown at 300, as per one embodiment of the present invention. A top surface of table base 302 is provided with permanent magnets 310, attached to rotating upper members 314. Tabletop 304 comprises first surface 306 and second surface 308, first surface 306 comprising a first ferromagnetic material, and second surface 308 comprising a second ferromagnetic material. These surfaces are alternately mounted to table base 302 by means of attraction between permanent magnets 310 and the first or second ferromagnetic materials. Rotating upper members 314 are rotatable by an appropriate square-head chuck wrench used on square hole 316. Rotating upper members 314 either moves permanent magnets 310 to attach or detach from the tabletop.

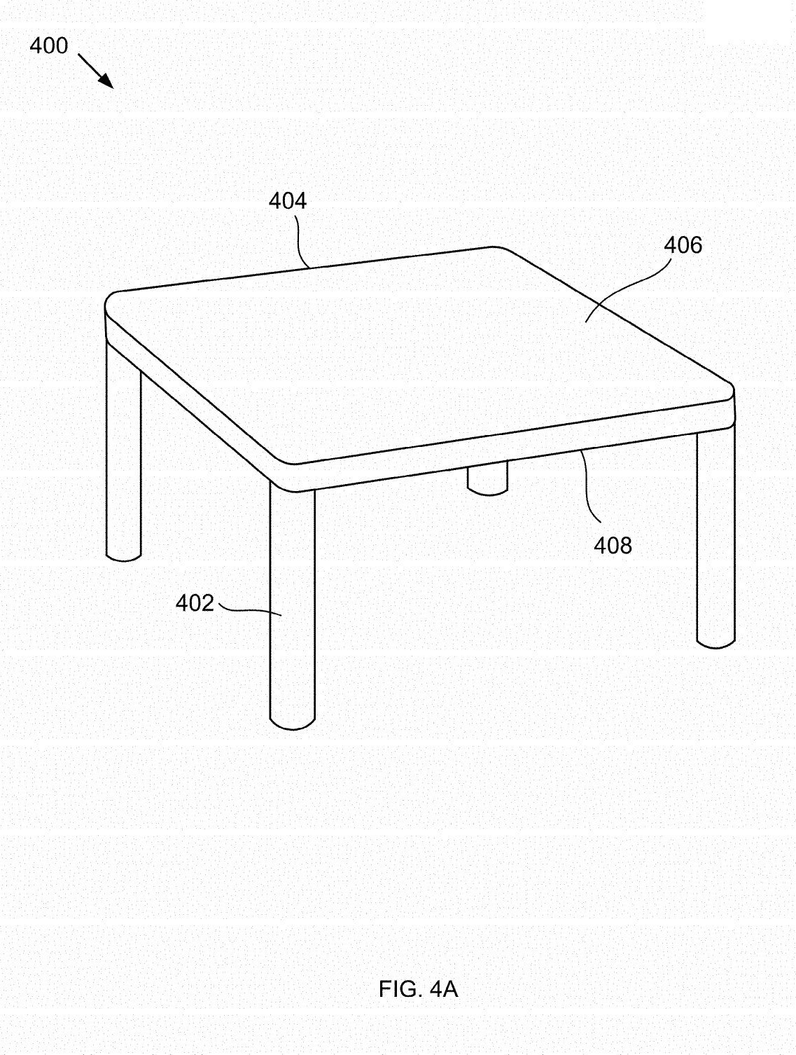

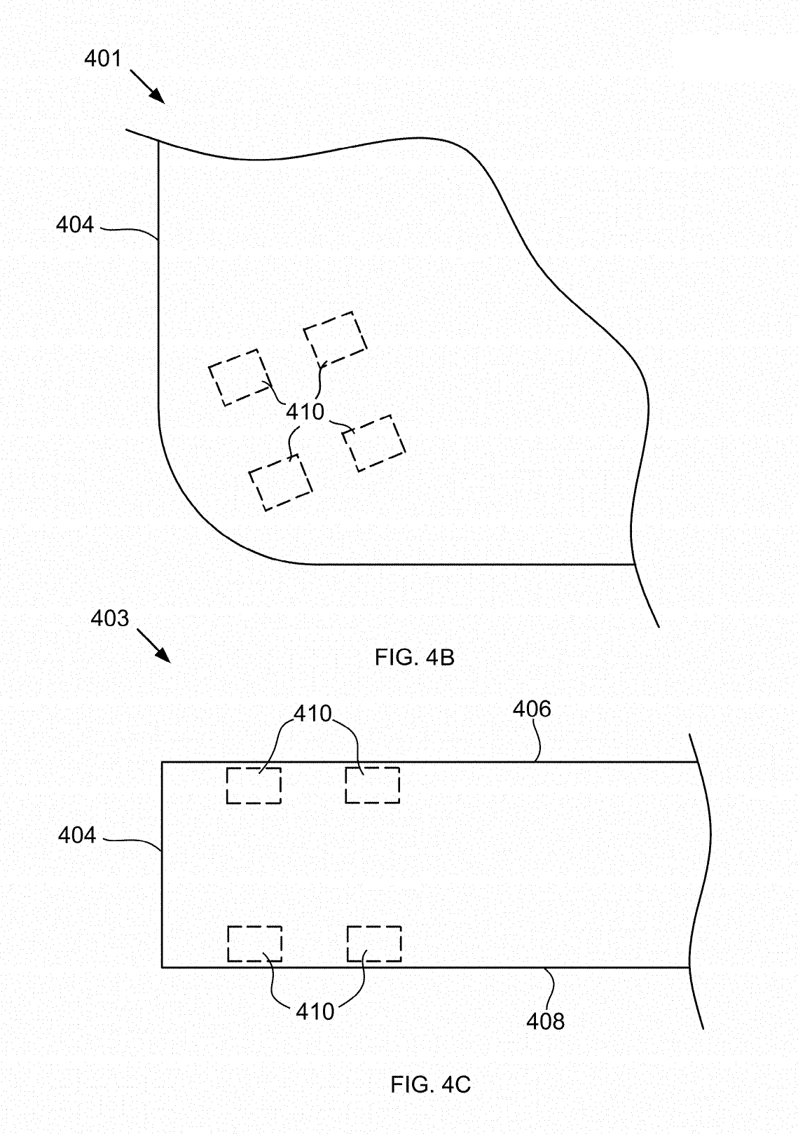

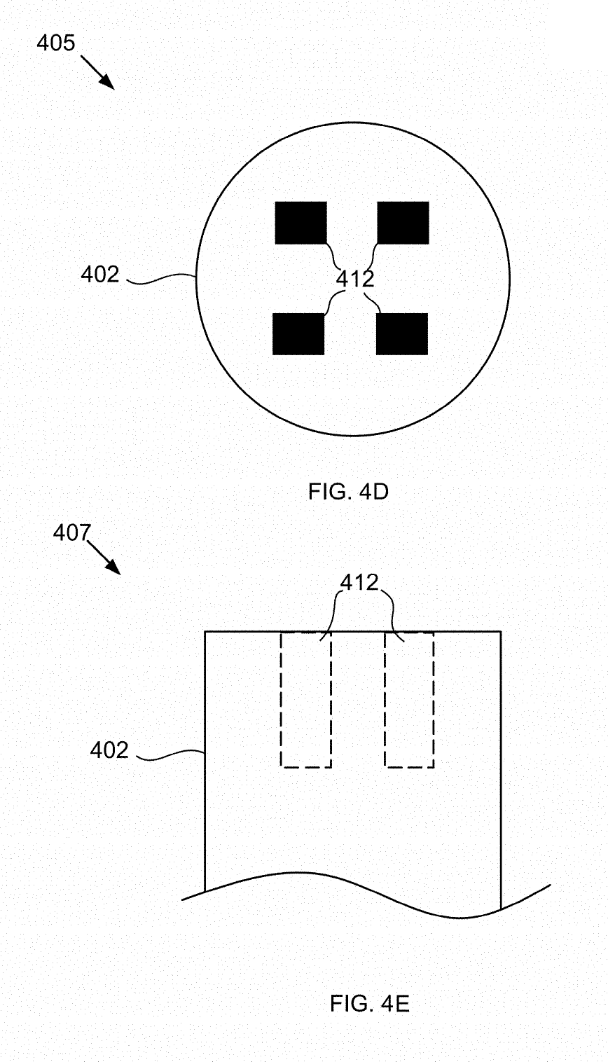

Referring to FIGS. 4A-E, an isometric view of a table is shown at 400, a top view and side view of one corner of the table are shown at 401 and 403, and a top view and side view of a table leg of the table are shown at 405 and 407, as per one embodiment of the present invention. A top surface of table legs 402 is provided with permanent magnets 412. Tabletop 404 comprises first surface 406 and second surface 408. Tabletop 404 further comprises ferromagnetic materials 410. First surface 406 and second surface 408 are alternately mounted to table legs 402 by means of attraction between permanent magnets 412 and ferromagnetic materials 410. Rotation of table legs 402 causes permanent magnets 412 and ferromagnetic materials 410 to rotate away from each other, causing the attraction to be reduced sufficient to allow tabletop 404 to be detached from table legs 402. In some embodiments, first surface 406 and second surface 408 are different materials. The permanent magnets may comprise an isotropic or anisotropic material comprising at least two magnetic pole orientations.

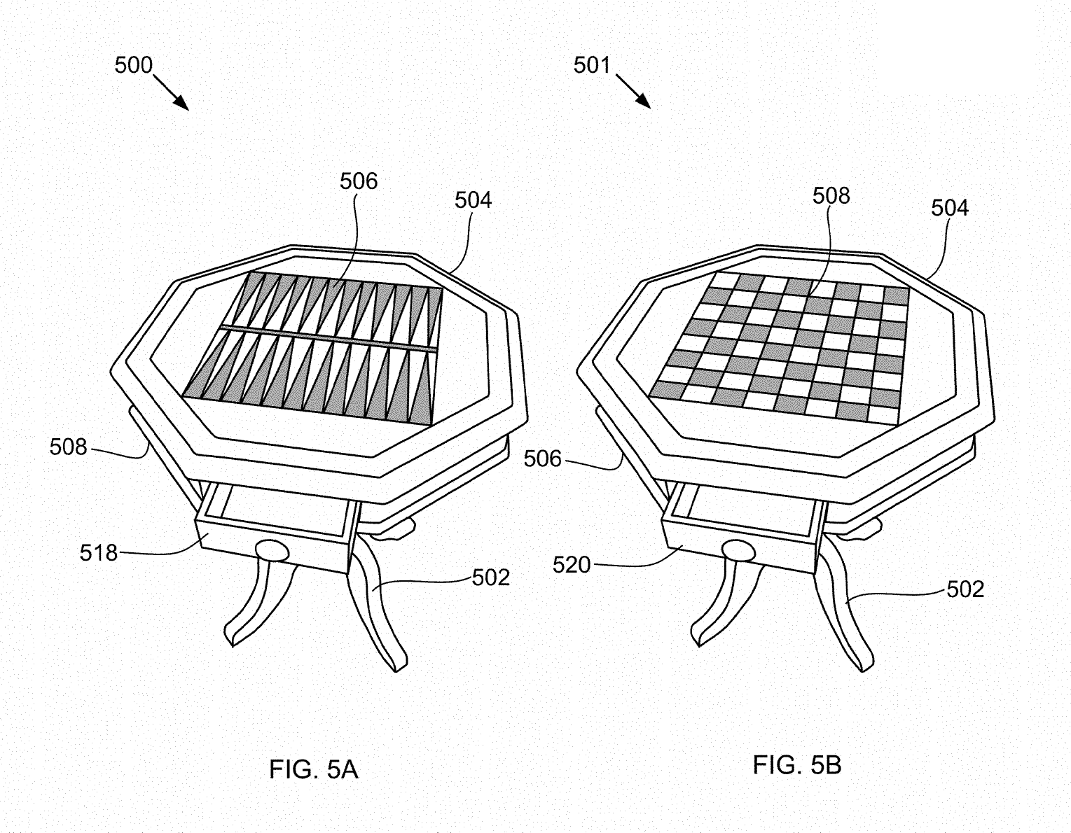

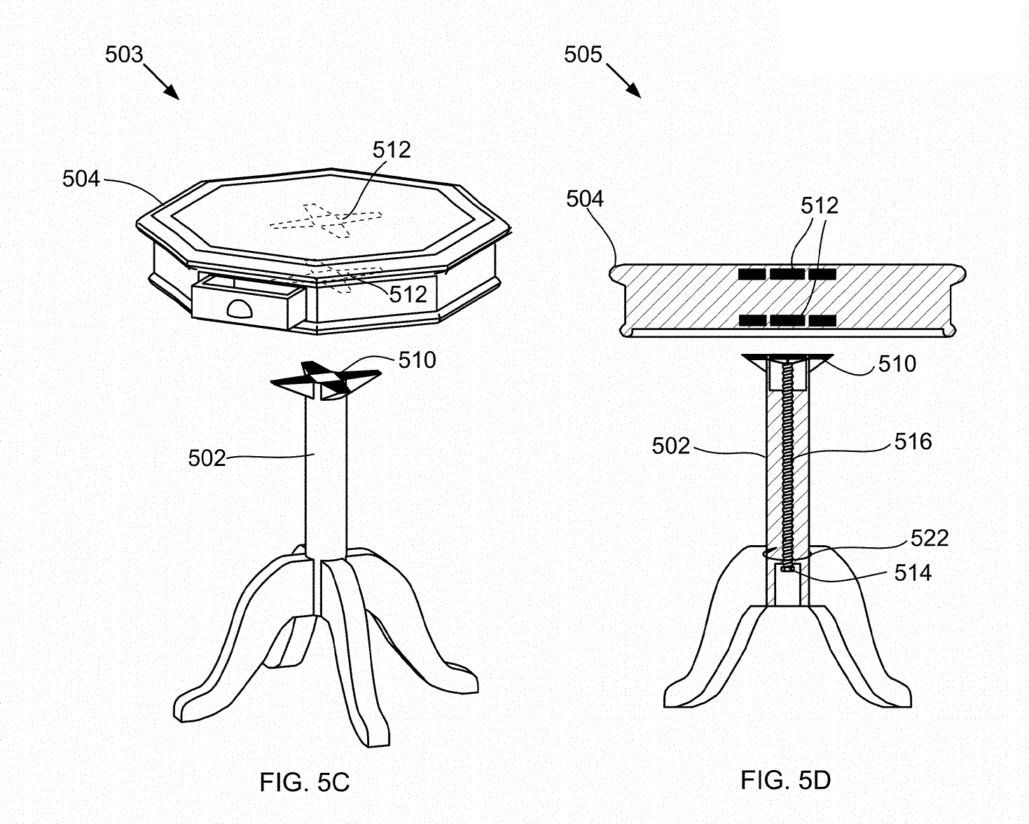

Referring to FIGS. 5A-D, isometric views of a table are shown at 500 and 501, a detached view of the table is shown at 503, and a cross-sectional detached side view of the table is shown at 505, as per one embodiment of the present invention. A top surface of table base 502 is provided with permanent magnets 510. Permanent magnets 510 is attached to bolt 514 by rod 516. Rotation 522 of bolt 514 causes permanent magnets 510 to rotate away from ferromagnetic materials 512. Tabletop 504 comprises first surface 506 and second surface 508, each surface comprising ferromagnetic materials 512 near the surface. These surfaces comprise backgammon and checkers, respectively, and are alternately mounted to table base 502 by means of attraction between permanent magnets 510 and ferromagnetic materials 512. Moving permanent magnets 510 away from ferromagnetic materials 512 by means of rotating bolt 514 detaches tabletop 504. Drawer 518 is blocked when first surface 506 is adhered to table base 502. Drawer 520 is blocked when second surface 508 is adhered to table base 502.

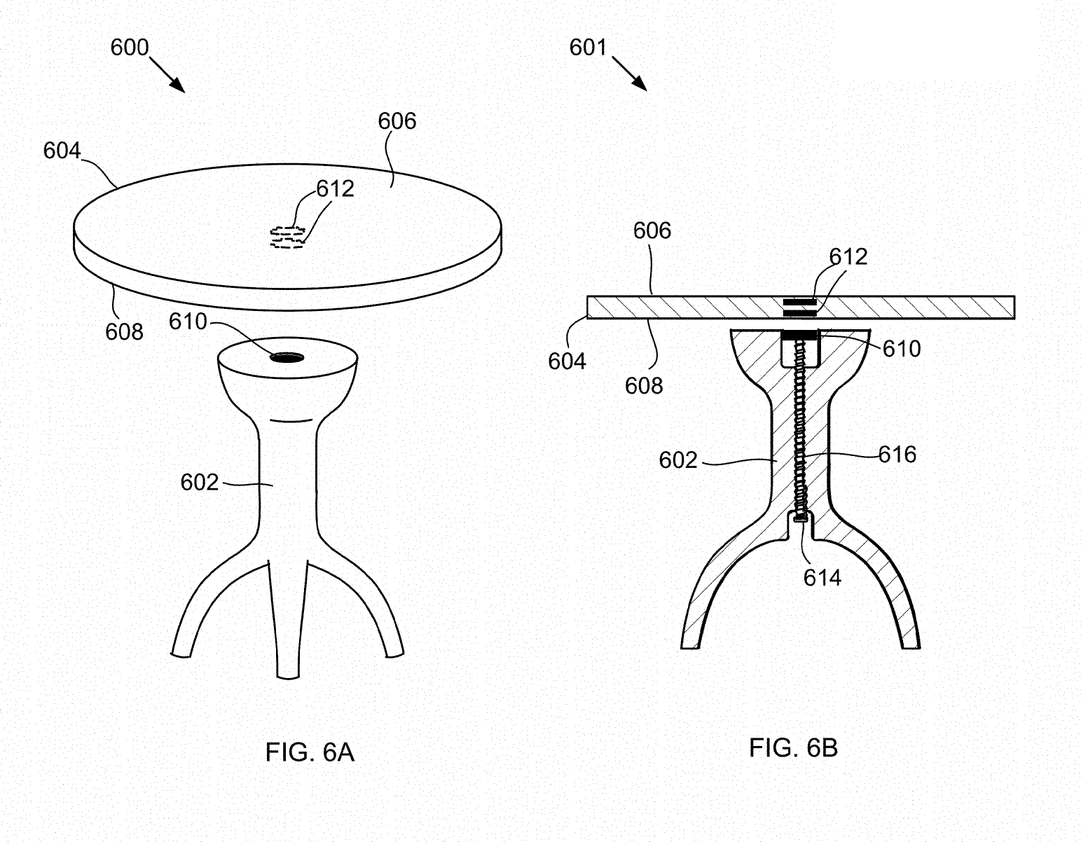

Referring to FIGS. 6A-B, an isometric view of a table is shown at 600 and a side view of the table is shown at 601, as per one embodiment of the present invention. A top surface of table base 602 is provided with permanent magnets 610. Permanent magnets 610 is attached to bolt 614 by rod 616. Rotation of bolt 614 causes permanent magnets 610 to move upwards or downwards. Tabletop 604 comprises first surface 606 and second surface 608, each surface comprising ferromagnetic materials 612 near the surface. These surfaces are alternately mounted to table base 602 by means of attraction between permanent magnets 610 and ferromagnetic material 612. Moving permanent magnets 610 away from tabletop 604 by means of rotating bolt 614 detaches tabletop 604. Drawer 614 is blocked when first surface 606 is adhered to table base 602. Drawer 616 is blocked when second surface 608 is adhered to table base 602.

In some embodiments, the one or more permanent magnets comprise neodymium iron boron magnets, samarium cobalt magnets, aluminum nickel cobalt magnets, ferritic magnets, or combinations thereof. The permanent magnets may comprise an isotropic or anisotropic material comprising at least two magnetic pole orientations.

In some embodiments, the first side and the second side are ferromagnetic. In some embodiments, the ferromagnetic material is contained within an interior portion of the tabletop.

In some embodiments, the rotatable portion comprises cross-bracing tubes horizontal to the tabletop. In some embodiments, the cross-bracing tubes comprise handles to facilitate rotation.

In some embodiments, the rotatable portion comprises one or more legs substantially perpendicular to the tabletop. In some embodiments, the one or more permanent magnets are arrayed in a pattern and the ferromagnetic material is arrayed in the pattern such that rotation of the one or more legs causes the pattern to alternately substantially overlap and substantially not overlap.

In some embodiments, the rotatable portion comprises cross-bracing tubes horizontal to the tabletop and one or more legs substantially perpendicular to the tabletop.

In some embodiments, the tabletop comprises an elevated pattern or patterns, a recessed pattern or patterns, or a combination thereof on the first side, the second side, or the first and the second side.

In some embodiments, the first side comprises a flush-mount touch screen computing device.

In some embodiments, the first side comprises a first smooth, uninterrupted surface and the second side comprises a second smooth, uninterrupted surface.

In some embodiments, the first side and the second side comprise different materials. In some embodiments, the first side and the second side further comprise bamboo, hard wood, plywood, laminated plywood, laminates, rubber, vinyl, plastics, stainless steel, galvanized steel, carbon steel, black iron, pewter, copper, zinc, aluminum, glass, quartz, granite, marble, stone, ceramics, fiberboards, varnish, sealant, paint, or combinations thereof. In some embodiments, the table base further comprises metal, wood, plastic, stone, glass, or combinations thereof.

In some embodiments, the table further comprises an electrical inlet or inlets, an electrical outlet or outlets, and an edge computer connection or connections in an edge or edges of the tabletop. In some embodiments, the table further comprises wiring passing through an interior portion of the tabletop between the edge computer connection or connections and a side computer connection or connections on the first side or the second side of the tabletop.

In some embodiments, the first side comprises a heating element or heating elements and the second side comprises a cooling element or elements.

In some embodiments, the first side and the second side comprise different uses, the uses selected from the group consisting of computer usage, office work, drafting, art, cutting, metal working, working with tools, cooking, dining, gaming, conferencing, displaying, medical, massage, or combinations thereof.

1. A table comprising:
a table base comprising a top surface comprising a rotatable portion comprising one or more permanent magnets, wherein the rotatable portion rotates independently from the table base;
a tabletop, wherein at least a portion of the tabletop comprises a ferromagnetic material;
the tabletop further comprising a usable first side and a usable second side alternately mounted to the table base by an attractive force between the ferromagnetic material and the one or more permanent magnets, wherein rotation of the rotatable portion of the top surface such that the one or more permanent magnets are oriented away from the ferromagnetic material engages or disengages the attractive force.

2. The table of claim 1, wherein the one or more permanent magnets comprise neodymium iron boron magnets, samarium cobalt magnets, aluminum nickel cobalt magnets, ferritic magnets, or combinations thereof.

3. The table of claim 2, wherein the first side and the second side are ferromagnetic.

4. The table of claim 2, wherein the ferromagnetic material is contained within an interior portion of the tabletop.

5. The table of claim 1, wherein the rotatable portion comprises cross-bracing tubes horizontal to the tabletop.

6. The table of claim 5, wherein the cross-bracing tubes comprise handles to facilitate rotation.

7. The table of claim 1, wherein the rotatable portion comprises one or more legs substantially perpendicular to the tabletop.

8. The table of claim 7, wherein the one or more permanent magnets are arrayed in a pattern and the ferromagnetic material is arrayed in the pattern such that rotation of the one or more legs causes the pattern to alternately substantially overlap and substantially not overlap.

9. The table of claim 1, wherein the rotatable portion comprises cross-bracing tubes horizontal to the tabletop and one or more legs substantially perpendicular to the tabletop.

10. The table of claim 1, wherein the tabletop comprises an elevated pattern or patterns, a recessed pattern or patterns, or a combination thereof on the first side, the second side, or the first and the second side.

11. The table of claim 1, wherein the first side comprises a flush-mount touch screen computing device.

12. The table of claim 1, wherein the first side comprises a first smooth, uninterrupted surface and the second side comprises a second smooth, uninterrupted surface.

13. The table of claim 1, wherein the first side and the second side comprise different materials.

14. The table of claim 13, wherein the first side and the second side further comprise bamboo, hard wood, plywood, laminated plywood, laminates, rubber, vinyl, plastics, stainless steel, galvanized steel, carbon steel, black iron, pewter, copper, zinc, aluminum, glass, quartz, granite, marble, stone, ceramics, fiberboards, varnish, sealant, paint, or combinations thereof.

15. The table of claim 1, wherein the table base further comprises metal, wood, plastic, stone, glass, or combinations thereof.

16. The table of claim 1, further comprising an electrical inlet or inlets, an electrical outlet or outlets, and an edge computer connection or connections in an edge or edges of the tabletop.

17. The table of claim 1, wherein the first side comprises a heating element or heating elements and the second side comprises a cooling element or elements.

18. The table of claim 1, wherein the first side and the second side comprise different uses, the uses selected from the group consisting of computer usage, office work, drafting, art, cutting, metal working, working with tools, cooking, dining, gaming, conferencing, displaying, medical, massage, or combinations thereof.

19. A table comprising:
a table base comprising a top surface comprising a rotatable portion comprising one or more permanent magnets, wherein:
the rotatable portion rotates independently from the table base;
the rotatable portion comprises cross-bracing tubes, legs, or combinations thereof;
the one or more permanent magnets comprise neodymium iron boron magnets, samarium cobalt magnets, aluminum nickel cobalt magnets, ferritic magnets, or combinations thereof;
a tabletop, at least a portion of the tabletop comprising a ferromagnetic material; and,
the tabletop further comprising a usable first side and a usable second side alternately mounted to the table base by an attractive force between the ferromagnetic material and the one or more permanent magnets, wherein:
rotation of the rotatable portion of the top surface such that the one or more permanent magnets are oriented away from the ferromagnetic material engages or disengages the attractive force;
the first side and the second side comprise different materials; and,
the first side and the second side further comprise bamboo, hard wood, plywood, laminated plywood, laminates, rubber, vinyl, plastics, stainless steel, galvanized steel, carbon steel, black iron, pewter, copper, zinc, aluminum, glass, quartz, granite, marble, stone, ceramics, fiberboards, varnish, sealant, paint, or combinations thereof.

20. The table of claim 1, wherein the permanent magnets comprise an isotropic or anisotropic material comprising at least two magnetic pole orientations.
